(19) United States
(12) Patent Application Publication
(10) Pub. No.: US 2007/0221917 A1
(43) Pub. Date: Sep. 27, 2007

(54) Method of preparing nanowire(s) and product(s) obtained therefrom

(76) Inventors: Wee Shong Chin, Singapore (SG); Chenmin Liu, Singapore (SG)

Correspondence Address: DICKSTEIN SHAPIRO LLP, 1825 EYE STREET NW, Washington, DC, 20006-5403, US

(21) Appl. No.: 11/727,126

(22) Filed: Mar. 23, 2007

Related U.S. Application Data
(60) Provisional application No. 60/785,277, filed on Mar. 24, 2006.

(51) Int. Cl. H01L 51/00; H01L 29/08

(52) U.S. Cl. 257/40; 438/101; 977/700

(57) ABSTRACT

The present invention provides a method of preparing at least one nanowire comprising the steps of: (a) providing at least one nanotemplate and at least one electrically conductive element in contact with the nanotemplate; (b) providing at least one organic linker, the organic linker having a first end and a second end, such that the first end is in contact with the electrically conductive element; and (c) performing at least one electrochemical deposition for the formation of at least one nanowire. The present invention also provides nanowires prepared according to the method of the invention.

### FIELD OF THE INVENTION

This application claims priority to U.S. provisional application 60/785,277, filed Mar. 24, 2006, the entire disclosure of which is incorporated herein by reference.

The present invention relates to a method of preparing nanowire(s). In particular, the nanowire(s) prepared are well-ordered and well-assembled. The present invention also relates to nanowires obtained from the method. The nanowires may be used in nanotechnology, particularly in nanoelectronics and nanodevices.

### BACKGROUND OF THE INVENTION

Artificially structured materials with nanometer-sized entities, such as nanowire arrays, have attracted more attention in recent years because of their distinctive properties and potential for technological applications. Their intricate properties are directly related to the low dimensionality of the entities and can be manipulated through the extra degrees of freedom inherent to their nanostructures. For example, arrays of metallic nanowires are attractive for their potential applications in high-density magnetic recording devices (S. Manalis et al, 1995; S. Y. Chou et al, 1994) and sensors (J. L. Simonds, 1995), as well as for fundamental scientific studies of nanomagnetics. The ability to produce highly ordered metallic nanowire arrays cheaply and effectively is important for both purposes.

Known methods for fabricating metallic nanowire arrays typically involve template-assisted electrochemical deposition, template-assisted crystallization of molten materials such as that described in U.S. Pat. No. 6,359,288, template-assisted precursor induced wet chemical deposition (T. M. Whitney et al, 1993; M. Motoyama et al, 2005; Z. A. Hu and H. L. Li, 2005; K. R. Pirota et al, 2004; A. J. Yin et al, 2001) and magnetic field induced alignment such as that described in U.S. Pat. No. 6,741,019. However, the yield of the nanowires produced from these methods is not high, and the nanowires in the arrays cannot be kept aligned in a well-ordered manner after removing the sustaining templates. One way of obtaining nanowire arrays in well-ordered patterns is to utilise multifarious sub-processes (Y Liang et al, 2004) or high temperatures (D Benerjee et al, 2003). However, this will not be cost-efficient when the nanowires are prepared in industrial-scale.

Self-assembled monolayers (SAMs) are well-suited for studies in nanoscience and nanotechnology. The functional groups at the surfaces of SAMs can assist in controlling crystal nucleation (B. C. Bunker et al, 1994; L. J. Prins et al, 1999; C. Chen and J. Lin, 2001). It has been proven that only the particles grown on the SAM would be bound to the substrate surface, and the nucleation is highly specific to the acid-terminated regions, and the crystals are remarkably uniform in size and nucleation density (J. C. Love et al, 2005). Some metals, as well as semiconductor nanoparticles, have been synthesized on patterned SAM surface (K. Hata et al, 2001). In some studies of metallic nanowires, the orthogonal functionalisation of different metallic sections with different SAMs was utilised (J. C. Love et al, 2005).

Accordingly, there is a need in the art for a suitable method which is capable of preparing nanowires in large scale and nanowires which are well-ordered.

### SUMMARY OF THE INVENTION

The present invention seeks to solve the problems above and provide a method for preparing nanowire(s). In particular, the present invention seeks to provide nanowires which are aligned in a well-ordered manner. The present invention also seeks to provide a method of quantitatively preparing nanowires in large scale. Even more in particular, the present invention makes use of organic linker groups that can self-assemble onto electrically conductive surfaces to direct and enhance the formation of nanowire arrays which are free-standing via electrochemical deposition.

According to a first aspect, the present invention provides a method of preparing at least one nanowire comprising the steps of:
(a) providing at least one nanotemplate and at least one electrically conductive element in contact with the nanotemplate;
(b) providing at least one organic linker, the organic linker having a first end and a second end, such that the first end is in contact with the electrically conductive element; and
(c) performing at least one electrochemical deposition for the formation of at least one nanowire.

The at least one electrically conductive element may be an electrically conductive layer. The at least one electrically conductive element may contact the nanotemplate on one surface of the nanotemplate.

The at least one nanowire formed from step (c) may be formed on the at least one electrically conductive element and/or on the second end of the organic linker. In particular, the at least one nanowire formed from step (c) may be joined to the at least one electrically conductive element and/or to the second end of the organic linker. The at least one nanowire may be formed such that it extends from the second end of the organic linker.

The at least one nanotemplate may be porous. Any suitable nanotemplate may be used. For example, the at least one nanotemplate may be anodic aluminium oxide (AAO) and/or titanium oxide.

The at least one organic linker in step (b) may be formed by immersing the at least one nanotemplate in a suitable solvent. The solvent may be an organic solvent comprising the organic linker. For example, the organic linker may be formed by immersing the at least one nanotemplate in a solvent comprising the organic linker and ethanol. The at least one organic linker may comprise a first end and a second end. The first end may be in contact with the at least one electrically conductive element. According to a particular aspect, the first end of the organic linker may comprise an anchoring group having an affinity for the at least one electrically conductive element and/or the second end of the organic linker may comprise an end group having an affinity for the at least one nanowire.

The anchoring group may be any suitable anchoring group which can attach to the electrically conductive element. The attachment may be by way of binding to the electrically conductive element, by adsorption, or the like. In particular, the anchoring group may be selected from the group consisting of: —SH, —CN, —COOH, —OH and —NH₂. Even more in particular, the anchoring group is —SH.

Any suitable organic linker may be used for the present invention. For example, the organic linker may be selected from the group consisting of: ROH, RCOOH, RNH₂, RSH, RSAc, RSR′, and RSSR′. Each R and R′ may be independently selected from the following: substituted or unsubstituted alkyl, alkenyl, alkynyl, aryl, cycloalkyl, cycloalkylene, cycloalkynyl, cycloaryl, heteroaryl, heteroalkyl, heterocycloaryl and heterocycloalkyl. In particular, the organic linker may be 11-mercaptoundecanoic acid (MUA).

The at least one electrically conductive element may comprise any material which is suitable for conducting electricity. The at least one electrically conductive element may comprise at least one metal. Any suitable metal which can form an electrically conductive element may be used for the purposes of the present invention. For example, the electrically conductive element may be selected from the group consisting of: gold (Au), nickel (Ni), copper (Cu), silver (Ag), palladium (Pd), platinum (Pt), mercury (Hg), cadmium (Cd), lead (Pb), silicon (Si), CdSe, CdS, PbS, oxides of silicon and combinations thereof. Alloys of metals may also be used. In particular, the electrically conductive element comprises gold (Au). The electrically conductive element may be formed according to any suitable method. In particular, the electrically conductive element may be formed by vacuum evaporation and/or plasma sputtering.

According to another particular aspect, the at least one electrochemical deposition of step (c) may be performed in the presence of an electrolyte. The electrolyte selected for the at least one electrochemical deposition of step (c) may depend on the type of nanowire to be prepared. Accordingly, any suitable electrolyte may be used. The electrolyte for each electrochemical deposition step may be the same or different. The electrolyte may be selected from the group consisting of: CuSO₄.6H₂O, NiSO₄.6H₂O, NiCl₂.6H₂O, H₃BO₃, AgNO₃, PbSO₄, gold plating solution (such as those provided by Technic Inc.) and a combination thereof. For example, when the copper nanowires are to be prepared according to the method of the present invention, the electrolyte may be CuSO₄.6H₂O. Alternatively, when nickel nanowires are to be prepared according to the method of the present invention, the electrolyte may be a combination of NiSO₄.6H₂O, NiCl₂.6H₂O and H₃BO₃. The at least one electrochemical deposition step may be carried out for a pre-determined period of time. The pre-determined period of time may be the same or different for each electrochemical deposition step.

The at least one nanowire formed in step (c) may be a first segment of at least one segmented nanowire. The method of the present invention may further comprise the step of: (d) performing at least one further electrochemical deposition for the formation of at least one further segment of the at least one nanowire, wherein the at least one further segment is joined to the first segment. The first segment and the at least one further segment may be longitudinally adjacent. The at least one further segment may be the same or different from the first segment. For example, the first segment may be copper and a second segment may be nickel, such that the nickel segment is joined to the copper segment to form a segmented nanowire. The lengths of the first segment and the further segments may be the same or different.

According to a further aspect, the present invention provides a method of preparing at least one segmented nanowire comprising the steps of:
(a) providing at least one nanotemplate and at least one electrically conductive element in contact with the nanotemplate;
(b) providing at least one organic linker, the organic linker having a first end and a second end, such that the first end is in contact with the electrically conductive element;
(c) performing a first electrochemical deposition for the formation of a first segment of nanowires under a first set of conditions; and
(d) performing a further electrochemical deposition for the formation of a further segment of nanowires under a second set of conditions, the further segment being joined to the segment formed in step (c).

The prepared segmented nanowires may be formed on the at least one electrically conductive element and/or on the second end of the organic linker. In particular, the first segment formed in step (c) may be joined to the at least one electrically conductive element and/or to the second end of the organic linker. The first segment may be formed such that it extends from the second end of the organic linker.

According to a particular aspect, steps (c) and (d) may be repeated at least once.

The at least one electrically conductive element and the at least one organic linker may be as described above. For example, the electrically conductive element and the at least one organic linker may be formed in the same manner as described above. The set of conditions for steps (c) and (d) may comprise: the electrolyte selected for the electrochemical deposition step; and the time period for which electrochemical deposition is performed. The conditions for each of steps (c) and (d) may be the same or different. For example, the electrolyte used in step (c) may be CuSO₄.6H₂O and the electrolyte used in step (d) may be a combination of NiSO₄.6H₂O, NiCl₂.6H₂O and H₃BO₃. Accordingly, a copper segment of nanowire may be prepared from step (c) and a nickel segment of nanowire may be prepared from step (d), the nickel segment being joined to the copper segment from the previous step. Steps (c) and (d) may be repeated sequentially, forming segments of copper and nickel in an alternating arrangement to form segmented nanowires.

The method according to any aspect of the present invention may further comprise the step of removing the at least one nanotemplate after the formation of the at least one nanowire or segmented nanowire. The at least one nanotemplate may be removed according to any suitable method. For example, the at least one nanotemplate may be removed by dissolving the nanotemplate in a suitable solvent. The solvent may be NaOH and/or HF. Alternatively, the at least one nanotemplate may be etched away by an amalgamation process.

The method according to any aspect of the present invention may further comprise the step of removing the at least one organic linker after the formation of the at least one nanowire or segmented nanowire. For example, the nanowire formed from the method according to any aspect of the present invention may be immersed in a suitable solution to remove the organic linker.

The present invention also provides nanowires prepared according to the method of any aspect of the present invention. The nanowires may be well-aligned and well-ordered. For example, at least about 50% of the nanowires may be substantially parallel to one another. At least about 60%, 70%, 75%, 80%, 85%, 90% or 95% of the nanowires may be substantially parallel to one another. The nanowires may be comprised in a nanowire-based device. The device may be magnetic recording devices, sensors, circuit elements, radiation detectors and thermophotolytic devices.

According to another aspect, the present invention provides devices comprising the nanowires prepared according to any method described above. The devices may be nanowire-based devices. For example, the devices may be selected from the group consisting of: magnetic recording devices, sensors, circuit elements, radiation detectors and thermophotolytic devices.

The present invention also provides an array of nanowires comprising nanowires prepared according to a method of any aspect of the present invention. The nanowires comprised in the array may be well-aligned and well-ordered. For example, at least about 50% of the nanowires may be substantially parallel to one another. At least about 60%, 70%, 75%, 80%, 85%, 90% or 95% of the nanowires may be substantially parallel to one another. The array of nanowires may be comprised in a nanowire-based device. The device may be magnetic recording devices, sensors, circuit elements, radiation detectors and thermophotolytic devices.

According to another aspect, the present invention provides a nanowire, wherein the nanowire is in contact with one end of at least one organic linker. The nanowire may be aligned and free-standing. The nanowire may be substantially perpendicular to the horizontal plane. For example, the nanowire may be substantially vertical relative to a horizontal plane.

### BRIEF DESCRIPTION OF THE FIGURES

FIG. 1: Scheme of preparing free-standing nanowire arrays.

FIG. 2: Copper nanowire arrays free-standing on gold substrate after removal of template. FIGS. 2a to 2d show the FESEM images from different visual fields.

FIG. 3: SEM image of side view of nickel nanowire arrays free-standing on gold substrate.

FIG. 4: XRD pattern of the as-synthesised copper nanowire array.

FIG. 5: SEM image of top view of nickel nanowire array free-standing on gold substrate after removal of template.

FIG. 6: SEM images of nickel nanowire arrays. (a) and (b) show the cross-sectional views and (c) and (d) show the self-formed patterns by the nickel nanowire arrays on the gold substrate.

FIG. 7: SEM image showing the multipeds that bridge with the gold substrate.

FIG. 8: SEM image showing the top view of a longer nickel nanowire array free-standing on gold substrate. The insert shows nanowires self-assembled into island to form a ‘crop circle’ structure.

FIG. 9: SEM images showing comparison of the ‘islands’ formed by the shorter and the longer nickel nanowire arrays. FIGS. 9(a) and (b) show ‘islands’ formed by 3 μm long nanowires and FIGS. 9(c) and (d) show ‘islands’ formed by 7 μm long nanowires.

FIG. 10: TEM images of separated Ni nanowires. FIG. 10(a) shows 3 dispersed nanowires and FIG. 10(b) shows a single nanowire.

FIG. 11: TEM image of a single nanowire and EDX spectrum corresponding to the root part of the nanowire (within the marked rectangular area).

FIG. 12: TEM image of the single nanowire of FIG. 11 and EDX spectrum corresponding to the trunk part of the nanowire (within the marked rectangular area).

FIG. 13: SEM image of gold nanowires free-standing on the substrate after the removal of AAO template.

FIG. 14: Cu/Ni segmented nanowire arrays free-standing on the substrate. FIGS. 14(a) and (b) show different visual fields.

FIG. 15: Au/Ni segmented nanowire arrays free-standing on the substrate.

FIG. 16: SEM images of Ni nanowires after the removal of AAO template and sonication for 30 minutes, (a) Ni nanowires prepared by electrochemical deposition without an organic linker and (b) Ni nanowires prepared by electrochemical deposition with an organic linker.

FIG. 17: SEM images of Cu nanowires after the removal of AAO template and sonication for 30 minutes, (a) Cu nanowires prepared by electrochemical deposition without an organic linker and (b) Cu nanowires prepared by electrochemical deposition with an organic linker.

### DETAILED DESCRIPTION OF THE INVENTION

Bibliographic references mentioned in the present specification are for convenience listed in the form of a list of references and added at the end of the examples. The whole content of such bibliographic references is herein incorporated by reference.

In the present invention, it was found that using the method of the present invention drastically improved the yield and the quality of nanowires prepared by adopting the electrochemical deposition method. The nanowires formed are well-ordered and well-aligned. Further, the nanowires formed remain free-standing, even after the nanotemplate on which they are prepared is removed. The method of the present invention is also suitable for the large-scale preparation of nanowires and/or nanowire arrays. The nanowires prepared from any method of the present invention may be used in other nanotechnology applications such as in nanoelectronics and manufacture of nanodevices.

According to a first aspect, the present invention provides a method of preparing at least one nanowire comprising the steps of:
(a) providing at least one nanotemplate and at least one electrically conductive element in contact with the nanotemplate;
(b) providing at least one organic linker, the organic linker having a first end and a second end, such that the first end is in contact with the electrically conductive element; and
(c) performing at least one electrochemical deposition for the formation of at least one nanowire.

In order to clarify nomenclature and definitions, terms relating to nanostructures are defined in accordance with the Classification Definitions of Class 977, published in April 2006 by the USPTO, the contents of which are incorporated herein by reference. For the purposes of the present invention, a nanowire will be defined as a nanostructure having a diameter in the range of about 1 nanometer (nm) to about 1000 nm. Nanowires are typically prepared from a metal or a semiconductor material. When wires prepared from metal or semiconductor materials are provided in the nanometer size range, some of the electronic and optical properties of the metal or semiconductor materials are different than the same properties of the same materials in larger sizes. Accordingly, in the nanometer-size range of dimensions, the physical dimensions of the materials may have a critical effect on the electronic and optical properties of the material.

The at least one nanowire may be formed on the at least one electrically conductive element and/or on the second end of the at least one organic linker. In particular, the at least one nanowire formed may be joined to the at least one electrically conductive element and/or to the second end of the at least one organic linker. Even more in particular, the at least one nanowire may be formed such that it extends from the second end of the at least one organic linker. The nanowire may be formed on the second end of at least one organic linker. In particular, the nanowire may be formed on the second end of at least two organic linkers. Even more in particular, the nanowire may be formed on the second end of at least three, four, five, six, seven, eight, nine or ten organic linkers.

The nanowires formed according to any aspect of the present invention may be of any suitable material. For example, the nanowires formed may be made of metals which include, but are not limited to, copper (Cu), nickel (Ni), tin (Sn), chromium (Cr), iron (Fe), silver (Ag), titanium (Ti), cobalt (Co), zinc (Zn), platinum (Pt), palladium (Pd), osmium (Os), gold (Au), lead (Pb), iridium (Ir), molybdenum (Mo), vanadium (V), aluminum (Al), or combinations thereof. In addition, non-limiting examples of metal oxides which the nanowires can be fabricated from include, but not limited to, tin dioxide (SnO₂), chromia (Cr₂O₃), iron oxide (Fe₂O₃, Fe₃O₄, or FeO), nickel oxide (NiO), silver oxide (AgO), titanium oxide (TiO₂), cobalt oxide (Co₂O₃, Co₃O₄, or CoO), zinc oxide (ZnO), platinum oxide (PtO), palladium oxide (PdO), vanadium oxide (VO₂), molybdenum oxide (MoO₂), lead oxide (PbO), and combinations thereof. In addition, a non-limiting example of a metalloid nanowire includes, but is not limited to, silicon, germanium or combinations thereof. Further, a non-limiting example of a metalloid oxide nanowire includes, but is not limited to, silicon monoxide, silicon dioxide, germanium monoxide, germanium dioxide or combinations thereof.

The nanowires formed according to any aspect of the present invention may have an average diameter of less than 500 nm. The average diameter of the nanowires formed may be from 50 nm to 300 nm. In particular, the average diameter may be from 100 nm to 200 nm. Even more in particular, from 150 nm to 190 nm. For example, the average diameter of the nanowires formed may be 170.0±20.0 nm. The average diameter of the nanowire may depend on the average pore diameter of the at least one nanotemplate.

According to another particular aspect of the present invention, the at least one nanotemplate used in any aspect of the present invention may be porous. The nanotemplate may be anodic aluminium oxide (AAO) and/or titanium oxide. For the purposes of the present invention, anodic aluminium oxide (AAO) and anodic aluminium membrane (AAM) will be taken to mean the same and will be used interchangeably. The nanotemplate may be formed by any suitable method. For example, the AAO nanotemplate may be formed using a modified two-step anodization method as disclosed in H. Masuda and K. Fukuda, 1995. As mentioned above, the average diameter of the nanopore of the at least one nanotemplate may determine the average diameter of the nanowires formed from the method according to any aspect of the present invention. Accordingly, the average diameter of the nanopores of the at least one nanotemplate may be from 10 nm to 600 nm. The average diameter may be from 50 nm to 300 nm. In particular, the average diameter may be from 100 nm to 200 nm. Even more in particular, the average diameter may be about 150 nm. Further, the average thickness of the at least one nanotemplate may be from 0.5 to 500 μm. In particular, the average thickness may be about 60 μm.

According to a particular aspect, the at least one electrically conductive element may comprise any material which is suitable for conducting electricity. The electrically conductive element may comprise a metal and/or a semiconductor material. The electrically conductive element may be an electrically conductive layer. Any suitable metal or semiconductor material which can form an electrically conductive layer may be used. The electrically conductive element may be any conductive film or functionalized metal or metal with a thin oxide layer or other supports including highly doped semiconductors. For example, the electrically conductive element may be selected from the group consisting of: gold (Au), nickel (Ni), copper (Cu), silver (Ag), palladium (Pd), platinum (Pt), mercury (Hg), cadmium (Cd), lead (Pb), silicon (Si), oxides of silicon, CdSe, CdS, PbS and combinations thereof The at least one electrically conductive element may comprise alloys of metals. In particular, the electrically conductive layer comprises gold. The at least one electrically conductive layer may also be referred to as the substrate or the working electrode for the preparation of the at least one nanowire.

The electrically conductive element may be formed according to any suitable method. The electrically conductive element may be provided such that it contacts at least one surface of the nanotemplate. In particular, the electrically conductive element is formed by vacuum evaporation and/or plasma sputtering. Other methods for forming the electrically conductive element may include deposition through a stencil mask, using lithography, or using electroplating.

The at least one organic linker in step (b) may be formed by immersing the at least one nanotemplate in a suitable solvent comprising the organic linker. The nanotemplate may be immersed in a suitable solvent for a pre-determined period of time. The solvent may be an organic solvent comprising the organic linker. In particular, the organic linker may be formed by immersing the nanotemplate in a solvent comprising the organic linker and ethanol. The at least one nanotemplate may be immersed in the solvent comprising the organic linker from 12 to 36 hours. In particular, the period is from 15 to 28 hours. Even more in particular., the period is about 24 hours.

The at least one organic linker comprises a first end and a second end. The first end may be in contact with the at least one electrically conductive element. According to a particular aspect, the first end of the organic linker may comprise an anchoring group having an affinity for the at least one electrically conductive element and/or the second end of the organic linker may comprise an end group having an affinity for the at least one nanowire.

The anchoring group may self-assemble on the at least one electrically conductive element to form a self-assembled monolayer to direct the subsequent formation of the at least one nanowire. The subsequent formation of the at least one nanowire may be by electrochemical deposition. The presence of the at least one organic linker may improve the yield of nanowire formation compared to conventional electrochemical deposition methods without the presence of such an organic linker. The at least one organic linker may comprise a carbon chain length which is sufficiently long for van der Waals forces to assist in the formation of the self-assembled monolayer. For example, the at least one organic linker may comprise a carbon chain with at least 3 carbon atoms. In particular, the at least one organic linker may comprise a carbon chain with at least 5 carbon atoms.

The anchoring group may be any suitable anchoring group which can attach to the electrically conductive element. The attachment may be by way of binding to the electrically conductive element, by adsorption, or the like. The anchoring group may be an organic linker group. In particular, the anchoring group may be selected from the group consisting of: —SH, —CN, —COOH, —OH and —NH₂. Other anchoring groups which may be used include, but are not limited to, thiol/thiolate, amine, imine, nitrile, isocyanide, phosphine, selenide, sulphide, silane, phosphonic acid, hydroxamic acid, hydroxilic acid functional group, or a combination thereof. Even more in particular, the anchoring group is —SH.

As the anchoring group has an affinity for the at least one electrically conductive element, it is essential that the selection of the electrically conducting material comprised in the at least one electrically conductive element and the organic linker comprising the anchoring group be appropriate. Different anchoring groups may only form stable bonds with certain electrically conductive substrates. Accordingly, any suitable organic linker may be used for the present invention. The organic linker may be selected from the group consisting of: ROH, RCOOH, RNH₂, RSH, RSAc, RSR′, and RSSR′. Each R and R′ may be independently selected from the following: substituted or unsubstituted alkyl, alkenyl, alkynyl, aryl, cycloalkyl, cycloalkylene, cycloalkynyl, cycloaryl, heteroaryl, heteroalkyl, heterocycloaryl and heterocycloalkyl.

The term “alkyl,” by itself or as part of another substituent, means, unless otherwise stated, a straight or branched chain, or cyclic hydrocarbon radical, or combination thereof, which may be fully saturated, mono- or polyunsaturated and can include di- and multivalent radicals, having the number of carbon atoms designated (i.e. C₁-C₁₀ means one to ten carbons). Examples of saturated hydrocarbon radicals include, but are not limited to, groups such as methyl, ethyl, n-propyl, isopropyl, n-butyl, t-butyl, isobutyl, sec-butyl, cyclohexyl, cyclohexylmethyl, cyclopropylmethyl, homologs and isomers of, for example, n-pentyl, n-hexyl, n-heptyl, n-octyl, and the like. An unsaturated alkyl group is one having one or more double bonds or triple bonds. Examples of unsaturated alkyl groups include, but are not limited to, vinyl, 2-propenyl, crotyl, 2-isopentenyl, 2-butadienyl, 2,4-pentadienyl, 3-(1,4-pentadienyl), ethynyl, 1- and 3-propynyl, 3-butynyl, and the higher homologs and isomers. The term “alkyl,” unless otherwise noted, is also meant to include those derivatives of alkyl, such as “heteroalkyl.” Alkyl groups which are limited to hydrocarbon groups are termed “homoalkyl”.

The term “alkenyl” includes mono-unsaturated hydrocarbon residues, including linear, branched and cyclic groups, of between two and six carbon atoms. Examples of alkenyl groups include, but are not limited to, vinyl, 1-propenyl, allyl, 2-methyl-2-propenyl, 2-butenyl, 3-cyclopentenyl and 2,3-dimethyl-2-butenyl groups.

The term “alkynyl” refers to an unsaturated alkyl group having one or more triple bonds. Examples of such unsaturated alkyl groups include vinyl, 2-propenyl, crotyl, 2-isopentenyl, 2-(butadienyl), 2,4-pentadienyl, 3-(1,4-pentadienyl), ethynyl, 1- and 3-propynyl, 3-butynyl, and the higher homologs and isomers.

The terms “cycloalkyl” and “heterocycloalkyl”, by themselves or in combination with other terms, represent, unless otherwise stated, cyclic versions of “alkyl” and “heteroalkyl”, respectively. Additionally, for heterocycloalkyl, a heteroatom can occupy the position at which the heterocycle is attached to the remainder of the molecule. Examples of cycloalkyl include, but are not limited to, cyclopentyl, cyclohexyl, 1-cyclohexenyl, 3-cyclohexenyl, cycloheptyl, and the like. Examples of heterocycloalkyl include, but are not limited to, 1-(1,2,5,6-tetrahydropyridyl), 1-piperidinyl, 2-piperidinyl, 3-piperidinyl, 4-morpholinyl, 3-morpholinyl, tetrahydrofuran-2-yl, tetrahydrofuran-3-yl, tetrahydrothien-2-yl, tetrahydrothien-3-yl, 1-piperazinyl, 2-piperazinyl, and the like.

The term “cycloalkylene” as employed herein refers to a “cycloalkyl” group which includes free bonds.

Aryl, as used herein refers to single or multiple 4 to 10 membered aromatic ring radicals including but not limited to phenyl, benzyl, naphthalene, indene and indacene. Preferred are phenyl, benzyl and naphthalene. In some embodiments of the present invention, the aryl group may be substituted.

Heteroaryl as used herein refers to single or multiple 4 to 10 membered aromatic ring radicals having from 1 to 3 heteroatoms selected from S, O or N including, but not limited to, furan, thiophene, pyrrole, imidazole, oxazole, thiazole, isoxazole, pyrazole, isothiazole, oxadiazole, triazole, thiadiazole, quinolizine, quinoline, isoquinoline, cinnoline, phthalazine, quinazoline, quinoxaline, napthyridine, pteridine, pyridine, pyrazine, pyrimidine, pyridazine, pyran, triazine, indole, isoindole, indazole, indolizine, and isobenzofuran. Preferred heteroaryls include furan, thiophene, pyrrole, imidazole, oxazole, thiazole, isoxazole, pyrazole, isoxazole, isothiazole, oxadiazole, triazole, thiadiazole, quinolizine, quinoline, and isoquinoline. More preferred heteroaryls include furan, thiophene, imidazole, isoxazole, quinoline, pyridine and pyrazole. In some embodiments of the present invention, the heteroaryl group is substituted.

The term cycloheteroaryl groups includes groups such as thiadiazaole, tetrazole, imidazole, or oxazole.

The term “heteroalkyl” by itself or in combination with another term, means, unless otherwise stated, a stable straight or branched chain, or cyclic hydrocarbon radical, or combinations thereof, consisting of the stated number of carbon atoms and at least one heteroatom selected from the group consisting of O, N, and S, and wherein the nitrogen and sulphur atoms may optionally be oxidized and the nitrogen heteroatom may optionally be quaternized. The heteroatom(s) O, N and S may be placed at any interior position of the heteroalkyl group or at the position at which the alkyl group is attached to the remainder of the molecule. Examples include, but are not limited to, —CH₂, —CH₂OCH₃, —CH₂CH₂NHCH₃, —CH₂CH₂N(CH₃)CH₃, —CH₂SCH₂CH₃, —CH₂CH₂, —S(O)CH₃, —CH₂CH₂S(O)₂CH₃, —CH═CHOCH₃, —Si(CH₃)₃, —CH₂CH═NOCH₃, and —CH═CHN(CH₃)CH₃.

For purposes of this specification, cycloalkynyl means groups of 5 to 20 carbon atoms, which include a ring of 3 to 20 carbon atoms. The alkynyl triple bond may be located anywhere in the group, with the proviso that if it is within a ring, such a ring must be 10 members or greater. Examples of “cycloalkynyl” are cyclododecyn-3-yl, 3-cyclohexyl-1-propyn-1-yl, and the like.

Suitable substitutions include, but are not limited to, halogen, alkyl, alkoxy, haloalkyl, haloalkoxy, hydroxy, nitro, nitrile, amino, cyano, carboxy, alkoxycarbonyl, alkylcarbonyl, alkoxycarbonylalkyl and alkylcarbonyloxy.

In particular, the organic linker may be 11-mercaptoundecanoic acid (MUA). A list of possible combinations of organic linkers and electrically conductive element which may be used for the present invention is provided in Table 1 and Table 2. The combinations provided in Table 1 and Table 2 are not intended to be limiting for the purposes of the present invention. Other combinations not listed in the table may be used.

TABLE 1
Combinations of anchoring group of organic
linker and electrically conductive material (R and R′ are as defined above)

| General | | |
|---|---|---|
| formula of | Electrically | |
| organic linker | conductive material | |
| showing the | comprised in | |
| anchoring | electrically | Examples of organic |
| group | conductive element | linker |
| R—OH | Si | |
| R—COO/ | Ni | C1—, C7—, C9—, C11—, |
| R—COOH | | C13—COOH |
| R—NH₂ | CdSe | C2—, C3—, C4—, C6—, C8—, |
| | | C12-diaminoalkyl; C3—, |
| | | C4—, C8—, C12—, C16—, |
| | | C18-alkylamine; |
| | | aminoacetic acid; and |
| | | oleylamine |
| R—SH | Ag, AgS, Au, CdSe, | C8, C10, C12 alkylthiols; |
| | CdS, Cu, Ni, PbS, | C2, C6, C8 dithiols, |
| | Pd, Pt, Zn, ZnS | benzendimenthanethiol |
| RSAc | Au | |
| RSR′ | Au | |
| RSSR′ | Ag, Au, CdS | |

TABLE 2
Combinations of organic linker, electrically
conductive material and nanowires which can be formed

| General | | |
|---|---|---|
| formula of | Electrically | |
| organic linker | conductive material | |
| showing the | comprised in | |
| anchoring | electrically | |
| group | conductive element | Nanowires |
| HS—R—OH | Si | Ag, AgS, Au, CdSe, |
| (R = C₁, | | CdS, Cu, Ni, PbS, Pd, |
| C₂ . . . C₁₈ alkyl | | Pt, Zn, ZnS, Au |
| chain or | | |
| aromatic | | |
| chain) | | |
| HS—R—COOH | Ni, Au, Cu | Ag, AgS, Au, CdSe, |
| (R = C₁, | | CdS, Cu, Ni, PbS, Pd, |
| C₂ . . . C₁₈ alkyl | | Pt, Zn, ZnS, Au |
| chain or | | |
| aromatic | | |
| chain) | | |
| HCOO—R—COOH | Ni | Ni |
| (R = C₁, | | |
| C₂ . . . C₁₈ alkyl | | |
| chain or | | |
| aromatic | | |
| chain) | | |
| HS—R—SH | Au, Ag, Cu, Ni, Pt | Ag, AgS, Au, CdSe, |
| (R = C₁, | | CdS, Cu, Ni, PbS, Pd, |
| C₂ . . . C₁₈ alkyl | | Pt, Zn, ZnS, Au |
| chain or | | |
| aromatic | | |
| chain) | | |
| HS—R—NH₂ | Au, Ag, Cu, Ni, Pt | CdSe |
| (R = C₁, | | |
| C₂ . . . C₁₈ alkyl | | |
| chain or | | |
| aromatic | | |
| chain) | | |
| HS—R—S—CH₂—COOH | Au, Ag, Cu, Ni, Pt | Au |
| (R = C₁, | | |
| C₂ . . . C₁₈ alkyl | | |
| chain or | | |
| aromatic | | |
| chain) | | |

For example, if the anchoring group is thiol (—SH), the electrically conductive element may comprise metals such as Ni, Cu, Au and Ag, as such metals can form stable metal-S bonds for the subsequent formation of nanowires. Therefore, different anchoring groups may only form stable metal-anchoring group bonds with specific metals. For example, —CN will form stable metal—CN bonds with Ag and Au. As a further example, —NH₂ will form stable metal-NH₂ bonds with CdSe. The anchoring group may serve as a bridging group between the subsequently formed nanowires and the at least one electrically conductive element.

According to another particular aspect, the at least one electrochemical deposition of step (c) may be performed in the presence of an electrolyte (electrochemical bath). The electrolyte selected for the at least one electrochemical deposition of step (c) may depend on the type of nanowire to be prepared. Accordingly, any suitable electrolyte may be used. The electrolyte for each electrochemical deposition step may be the same or different. The electrolyte may be selected from the group consisting of: CuSO₄.6H₂O, NiSO₄.6H₂O, NiCl₂.6H₂O, H₃BO₃, AgNo₃, PbSO₄ and a combination thereof The electrolyte may also be a gold plating solution. The gold plating solution may be those provided by Technic Inc. For example, when the copper nanowires are to be prepared according to the method of the present invention, the electrolyte may be CuSO₄.6H₂O. Alternatively, when nickel nanowires are to be prepared according to the method of the present invention, the electrolyte may be a combination of NiSO₄.6H₂O, NiCl₂.6H₂O and H₃BO₃.

The electrochemical deposition step may be carried out in a three electrode electrochemical set-up that contains a working electrode, a reference electrode, and a counter electrode. For electrochemical deposition to occur the working electrode must be conducting. During the at least one electrochemical deposition step the at least one electrically conductive element may form the working electrode. Further electrodes may be provided for the electrochemical deposition to form the at least one nanowire. In particular, two further electrodes are provided—the reference electrode and the counter electrode. The reference electrode and the counter electrode may be of any suitable material. For example, the reference electrode may be Ag/AgCl and the counter electrode may be platinum.

The at least one electrochemical deposition step may be carried out for a pre-determined period of time for the formation of the at least one nanowire. The pre-determined period of time may be the same or different for each electrochemical deposition step. The pre-determined period of time may depend on the type of nanowire being formed. Different materials may require different deposition time. For example, the at least one electrochemical deposition may be carried out from 10 minutes to 2 hours. The duration of the electrochemical deposition step may affect the length and/or thickness of the at least one nanowire formed. Other conditions and parameters may also have to be altered. These include the voltage at which electrochemical deposition is being performed and the charge passing through the electrochemical deposition set up.

According to another particular aspect, the at least one nanowire formed in step (c) may be a first segment of at least one segmented nanowire. Therefore, the method of the present invention may further comprise the step of: (d) performing at least one further electrochemical deposition for the formation of at least one further segment of the at least one nanowire, wherein the at least one further segment may be joined to the first segment. As a result, segmented nanowires may be prepared. The first segment and the at least one further segment may be longitudinally adjacent to one another. The at least one further segment may be the same or different from the first segment. For example, a first segment may be copper and a second segment may be nickel, such that the nickel segment is joined to the copper segment to form a segmented nanowire. The lengths of the first segment and the further segments may be the same or different.

The method may further comprise the step of removing the at least one nanotemplate after the formation of the at least one nanowire. The step of removing the at least one nanotemplate may comprise dissolving the at least one nanotemplate in a suitable solvent. For example, the solvent may be NaOH and/or HF. Alternatively, the at least one nanotemplate may be etched away by an amalgamation process.

The method according to the present invention may further comprise a step of removing the at least one organic linker after the formation of the at least one nanowire. For example, the nanowire formed from the method according to any aspect of the present invention may be immersed in a suitable solution to remove the organic linker.

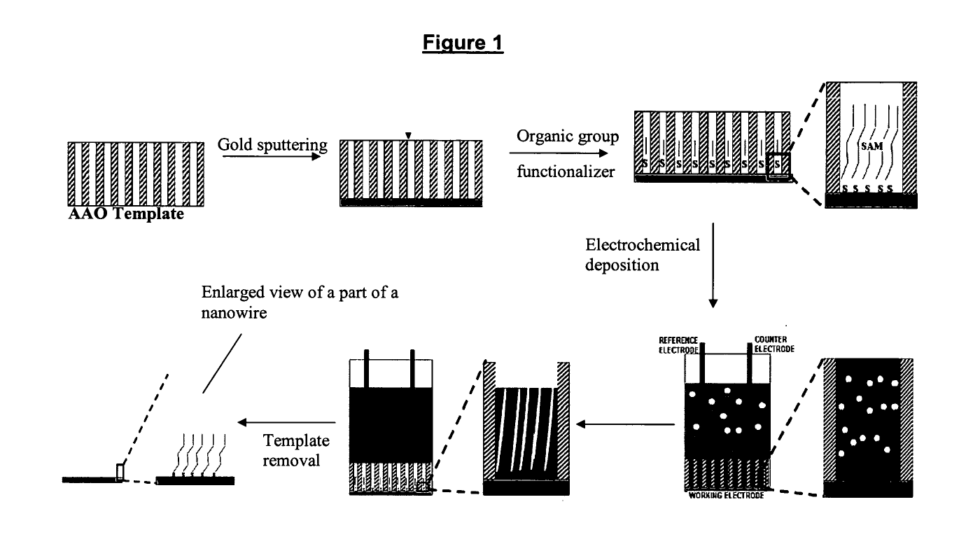

A general illustration of the method of the present invention is shown in FIG. 1. It should be noted that the particularity of FIG. 1 is not intended to be limiting to the present invention. For the purposes of the illustration in FIG. 1, AAO is used as the nanotemplate, and a layer of sputtered gold on one side of the AAO nanotemplate is used as the working electrode. An anchoring group comprising thiol (—SH) of the organic linker is introduced into the nanopores of the AAO nanotemplate which self-assemble at the bottom of the surface of the working electrode. Electrochemical deposition is then carried out, during which metallic ions are attracted into the AAO nanopores due to the second end group of the organic linker, thus forming nanowires within the nanopores of the AAO nanotemplate. The nanowires are joined to the second end group of the organic linker. FIG. 1 shows that each nanowire may be joined to more than one second end group.

According to another aspect, the present invention provides a method of preparing at least one segmented nanowire comprising the steps of:
(a) providing at least one nanotemplate and at least one electrically conductive element in contact with the nanotemplate;
(b) providing at least one organic linker, the organic linker having a first end and a second end, such that the first end is in contact with the electrically conductive element;
(c) performing a first electrochemical deposition for the formation of a first segment of at least one nanowire under a first set of conditions; and
(d) performing a second electrochemical deposition for the formation of a further segment under a second set of conditions, the further segment being joined to the segment formed in step (c).

The prepared segmented nanowires may be formed on the at least one electrically conductive element and/or the second end of the organic linker. In particular, the first segment formed in step (c) may be joined to the at least one electrically conductive element and/or to the second end of the organic linker. The first segment may be formed such that it extends from the second end of the linker.

According to a particular aspect, steps (c) and (d) may be repeated at least once. The segments formed in steps (c) and (d) may be of a pre-determined length. The length of the segment formed in each of steps (c) and (d) may be the same or different. The material of each segment formed in each of steps (c) and (d) may be the same or different.

The at least one nanotemplate and the at least one electrically conductive element may be as described above. The at least one organic linker may be selected as described above. The set of conditions for each of steps (c) and (d) may be the same or different. The conditions for each electrochemical deposition step (c) and/or (d) may be as described above. For example, the set of conditions for steps (c) and (d) may comprise: the electrolyte (electrochemical bath) selected for the electrochemical deposition step; and/or the duration for which electrochemical deposition is performed. The conditions may also include parameters such as the voltage applied to the set-up and the amount of charge passing through the set-up.

As a non-limiting example, the electrolyte used in step (c) may be CuSO₄.6H₂O and the electrolyte used in step (d) may be a combination of NiSO₄.6H₂O, NiCl₂.6H₂O and H₃BO₃. Accordingly, a copper segment of a segmented nanowire may be prepared from step (c) and a nickel segment of the segmented nanowire may be prepared from step (d), the nickel segment being joined to the copper segment prepared from the previous step. Steps (c) and (d) may be repeated sequentially, forming segments of copper and nickel in an alternating arrangement to form segmented Cu—Ni nanowires.

According to a particular aspect, it may be possible to electrodeposit two or more different metals from a single electrolyte bath to form the at least one nanowire. A single electrolytic bath comprising the ions of each of the metals to be deposited for the at least one nanowire formation may be used. Alternatively, separate electrolytes may be used for each metal to be deposited to form the nanowire. When a single electrolyte bath is used, it is essential to understand the processes occurring at the cathodic end of the electrochemical cell. For example, the most effective tool for analysing the electrochemical processes at the electrodes is by utilising a voltammogram. Voltammograms provide a graph of the current against electrode potential. Such a graph provides the information necessary to select the appropriate potential for the reduction of a desired metal. For example, for the purposes of selective electrodeposition of two segments composed of two different metals, it is essential that there is some separation between the reduction peaks that resemble each metal. If the two metals have overlapping reduction peaks in the voltammogram, it would be impossible to selectively electrodeposit two segments composed of two different metals from a single electrolyte solution. In this case, an alloy will be formed and the amount of each metal electrodeposited will be determined primarily by their relative concentrations in the electrolyte solution. On the other hand, if the two peaks are clearly separated, one can reduce only the first desired metal at some potential to form a first segment of a nanowire and reduce only the second desired metal at another potential to form the second segment of the nanowire.

The method may further comprise the step of removing the at least one nanotemplate after the formation of the segmented nanowires. The step of removing the at least one nanotemplate may be as described above. For example, the step of removing the at least one nanotemplate may comprise dissolving the at least one nanotemplate in a suitable solvent. For example, the solvent may be NaOH and/or HF. Alternatively, the at least one nanotemplate may be etched away by an amalgamation process.

The method according to the present invention may further comprise a step of removing the at least one organic linker after the formation of the at least one segmented nanowire. For example, the segmented nanowire formed from the method according to any aspect of the present invention may be immersed in a suitable solution to remove the organic linker.

The present invention also provides nanowires or segmented nanowires prepared according to the method of any aspect of the present invention. The nanowires or segmented nanowires may be aligned. In particular, the nanowires or segmented nanowires may be aligned to one another. The nanowires may be well-aligned and well-ordered even after the removal of the at least one nanotemplate. For the purposes of the present invention, a nanowire will be considered to be aligned when the nanowire is substantially parallel relative to another nanowire. For example, at least about 50% of the nanowires or segmented nanowires may be substantially parallel to one another. At least about 60%, 70%, 75%, 80%, 85%, 90% or 95% of the nanowires or segmented nanowires may be substantially parallel to one another.

Further, the nanowires or segmented nanowires prepared according to any method of the present invention may have a uniform diameter. The average diameter of the nanowires and segmented nanowires may depend on the average size of the nanopores of the at least one nanotemplate, as described above. The nanowires or segmented nanowires may have improved magentic recording properties and/or capacities. The nanowires and/or segmented nanowires may comprise a multiped head. The nanowires and/or segmented nanowires may be comprised in a nanowire- based device. The device may be magnetic recording devices, sensors, circuit elements, radiation detectors and thermophotolytic devices.

According to another aspect, the present invention provides devices comprising the nanowires prepared according to any method described above. The devices may be nanowire-based devices. For example, the devices may be selected from the group consisting of: magnetic recording devices, sensors, circuit elements, radiation detectors and thermophotolytic devices.

The present invention also provides an array of nanowires comprising nanowires and/or segmented nanowires prepared according to the method of any aspect of the present invention. The nanowires or segmented nanowires comprised in the array of nanowires may be aligned to one another. The nanowires and/or segmented nanowires comprised in the array may be well-aligned and well-ordered. For example, at least about 50% of the nanowires and/or segmented nanowires may be substantially parallel to one another. At least about 60%, 70%, 75%, 80%, 85%, 90% or 95% of the nanowires and/or segmented nanowires may be substantially parallel to one another. The array of nanowires may be comprised in a nanowire-based device. The device may be magnetic recording devices, sensors, circuit elements, radiation detectors and thermophotolytic devices.

According to another aspect, the present invention provides a nanowire, wherein the nanowire is in contact with one end of at least one organic linker. The organic linker may be as described above. The organic linker may have a first end and a second end. The first end may comprise an anchoring group which has an affinity for an electrically conductive element. The second end may have an affinity for the nanowire. The anchoring group and organic linker may be as described above. The nanowire may be made of suitable materials as described above.

The nanowire may be aligned and free-standing. The nanowire may be substantially perpendicular to the horizontal plane. For example, the nanowire may be substantially vertical relative to a horizontal plane. As a further example, if there are two or more nanowires, the two or more nanowires may be substantially parallel to one another.

According to a particular aspect, the nanowire may be a segmented nanowire, such as that described above. The nanowire may be used in nanowire-based devices such as magnetic recording devices, sensors, circuit elements, radiation detectors and thermophotolytic devices. The nanowires or segmented nanowires may form an array of nanowires. The array of nanowires may be used in nanowire-based devices as described above.

The nanowires according to any aspect of the present invention may be tested for their degree of order relative to other nanowires. An example of a test is to subject nanowires to sonication for a pre-determined period of time. For example, a standard sonication procedure may be carried out for about 30 minutes. The nanowires may then be observed under a scanning electron microscope (SEM) to determine from the images obtained whether the nanowires remain well-ordered and free-standing after the sonication is carried out on the nanowires. As described in the example below, the nanowires prepared from the method of the present invention remained well-ordered and well-aligned even after being subjected to sonication.

Having now generally described the invention, the same will be more readily understood through reference to the following examples which are provided by way of illustration, and are not intended to be limiting of the present invention.

### EXAMPLES

Materials

Nickel sufate hexahydrate (NiSO₄.6H₂O), 11-mercaptoundecanoic acid (MUA) from Aldrich, nickel chloride hexahydrate (NiCl₂.6H₂O), copper (II) sulfate pentahydrate (CuSO₄.5H₂O), sodium hydroxide (NaOH), hydrochloric acid (HCl) and sulfuric acid (H₂SO₄) from Merck, boric acid (H₃BO₃) from Fisher Scientific, were used as received without further purification. All glassware was washed with chromic acid and distilled water in succession and dried in an oven before use. Alumina membranes (Anodisc 47) with 150 nm pore diameters were obtained from Whatman International Ltd (Maidstone, England). All glassware was washed with chromic acid and distilled water in succession and dried in an oven before use. The physical vapour deposition of metal made use of a vacuum evaporator of Discovery®-18 Sputtering System. Electroplating was carried out on an Autolab PGSTA30 potentiostat/galvanostat controlled by the General Purpose Electrochemical System (version 4.6) software. A JEOL JSM-6700F microscope was used to obtain all field emission scanning electron microscope (FESEM) images. Further microstructural and elemental analyses were performed using a Philips CM300 FEG instrument with an acceleration voltage of 300 kV. Powder X-ray diffraction (XRD) patterns were recorded by a Siemens D5005 X-ray powder diffractometer with CuKα radiation (40 kV, 40 mA).

Synthesis of Nanowire Arrays

Anodic aluminium oxide (AAO) nanotemplate (Anodisc 47, Whatman International Ltd, England) having a thickness of 60 μm with pores of an average diameter of 150 nm were used as the template. Firstly, 150 nm of Au was deposited by standard vacuum evaporation onto one side of the AAO nanotemplate to form the working electrode. Before the electrochemical deposition was carried out, the AAO (with Au layer on one side) was immersed in 50 mM MUA (11-mercaptoundecanoic acid) in ethanol solution for 24 hours. Electrochemical deposition was then performed.
(i) Copper Nanowires

Copper was electroplated from an aqueous solution of 1M CuSO₄.6H₂O (pH=1, adjusted using H₂SO₄) at a constant voltage of −0.222 V vs. saturated calomel electrode (SCE). The electrochemical deposition was carried out for about 1000 seconds at room temperature and pressure.
(ii) Nickel Nanowires

Nickel was electroplated under a constant current density of −4.4 mA/cm² from a typical Watts bath: NiSO₄.6H₂O (165 g/L), NiCl₂.6H₂O (22.5 g/L), H₃BO₃ (37 g/L), and having a pH from 3 to 4. The electrochemical deposition was carried out for about 1500 seconds at room temperature and pressure.
(iii) Segmented Copper and Nickel Nanowires

For the preparation of segmented nanowire arrays consisting of Ni and Cu, one metal was plated at a time in the same manner as that described above in (ii) and (i) respectively for each of Ni and Cu, each for a predetermined period of time, followed by rinsing the membrane with 18 MΩ ultrapure water and applying a constant current density of −4.4 mA/cm² until the potential was more negative than −4 V. The current density was then restored to the value appropriate for the next metal deposition. The electrochemical deposition time for Cu was about 1000 seconds and for nickel it was about 1500 seconds.
(iv) Gold Nanowires

For the preparation of gold nanowires, gold was electroplated directly from commercial gold plating solution obtained from Technic Inc. (Otemp RTU24). A constant current density of −4.4 mA/cm² was applied. The electrochemical deposition was carried out for about 3000 seconds.
(v) Segmented Gold and Nickel Nanowires

For the preparation of segmented nanowire arrays consisting of Au and Ni, one metal was plated at a time in the same manner as that described above in (iv) and (ii) respectively for Au and Ni, each for a predetermined period of time, followed by rinsing the membrane with 18 MΩ ultrapure water and applying a constant current density of −4.4 mA/cm² until the potential was more negative than −4 V. The current density was then restored to the value appropriate for the next metal deposition. The electrochemical deposition time for Au was about 3000 seconds and for nickel, it was about 1500 seconds.

After the electrochemical deposition of nanowires, an aqueous solution of 1M NaOH was used to dissolve the AAO template. The nanowire arrays attached to the remaining gold foil were repeatedly rinsed with distilled water and ethanol to remove any residue of bases and salts.

Sonication

Copper and nickel nanowires prepared according to (i) and (ii) above were subjected to 30 minutes of sonication following standard sonication protocol. Copper and nickel nanowires prepared by only electrochemical deposition alone and without the use of any organic linker groups were prepared. These nanowires were also subjected to sonication under the same conditions as a basis of comparison.

Results and Discussion

The nanowires obtained were characterised by obtaining FESEM images, XRD patterns, TEM images and EDX spectrums.

For example, for TEM measurements the treatment of the samples is important. A piece of gold substrate with nanowire arrays free-standing on it was shaken in ultrasonic bath for more than 30 minutes, and the solution was then repeatedly centrifuged and washed with distilled water. The residuals were completely transferred into 1 mL of ethanol. A carbon grid was dipped in this dispersed solution, and it was vacuum dried before TEM observation was conducted.

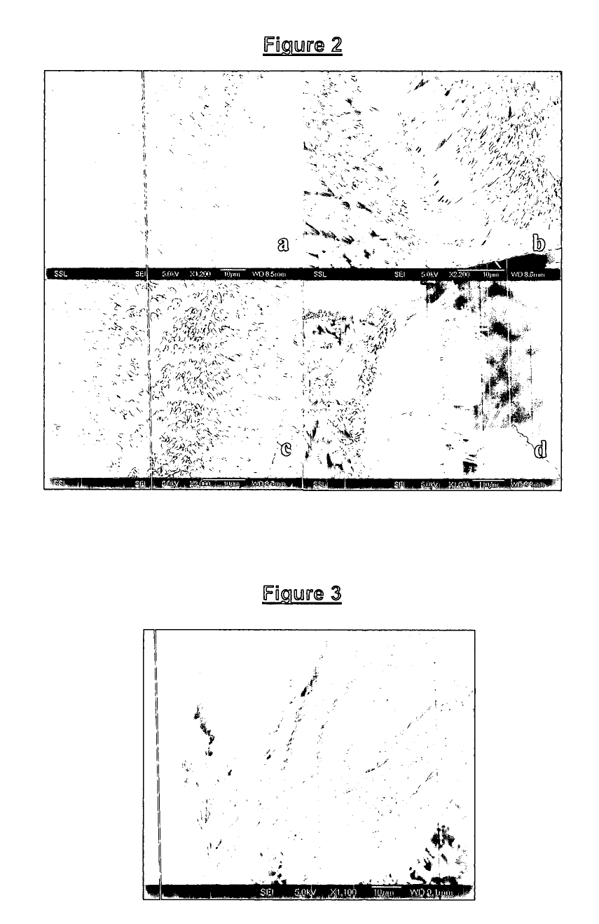

FIGS. 2 and 3 show the FESEM images of copper nanowire arrays free-standing on the gold substrate after the removal of the AAO template. The diameter of the nanowires varied from 150 nm to 190 nm with an average of 170.0±20.0 nm because of the non-uniformity in the pore size distribution of the AAO template. The length of the nanowires could be controlled by the total charge passed through the system. The nanowires obtained by the present method (i) were of relatively uniform length of about 7 μm. The length of the nanowires prepared according to the (ii) and (iv) were approximately 3 μm.

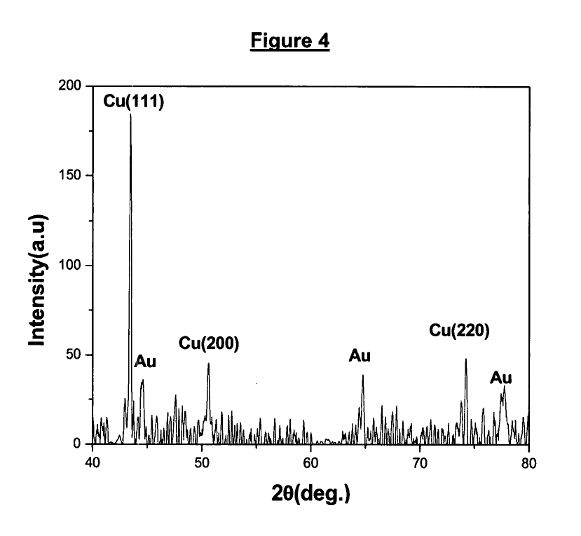

The yield of the nanowire arrays obtained was rather high and the nanowires were free-standing and well-aligned, as is evident from the images. The XRD pattern is shown in FIG. 4. It is observed that the other peaks are quite similar to that of Cu with FCC structure (JCPDS 04-0836). This indicates that the electrodeposited Cu is highly crystalline. The gold peaks indexed to gold arise from the gold substrate.

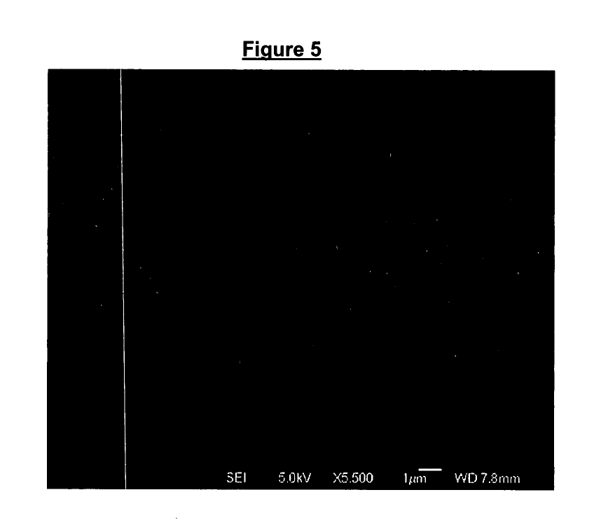

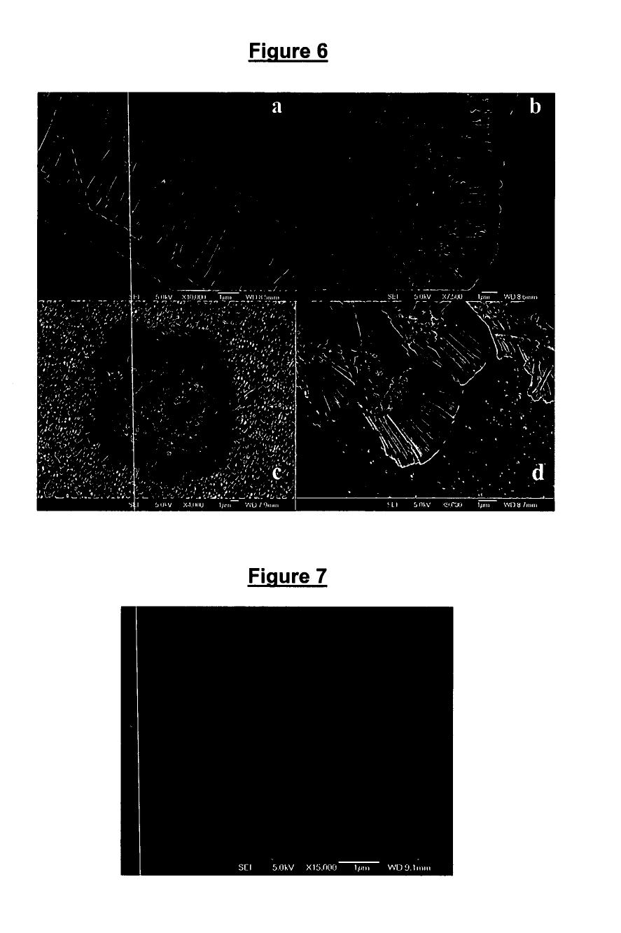

The SEM images of free-standing nickel nanowires array prepared from the method described above is shown in FIGS. 5 and 6. Few microscopic defects are observed in the figures. For example, FIG. 5 reveals a top view of the nanowires where the AAO template has been dissolved away. As shown, the nickel nanowires deposited into the nanopores of the AAO template are aligned in order and uniformly distributed. It is seen from the large visual field of FIG. 5 that abundant nickel nanowires are fabricated from the method and the nanowires are uniform and well-ordered in large areas. A different angle view (FIGS. 6(a) and 6(b)) demonstrates that almost all the Ni nanowires are electrodeposited perpendicularly onto the gold substrate, and the height of each nanowire is constant at about 3 μm. This result suggests that the metal nanowires grow uniformly during electrochemical deposition in each nanopore of the AAO template, and that the uniformity of macroscopic current density distribution can be transferred even to the array of nano-sized pores along the radial direction inside the cavity of the AAO template.

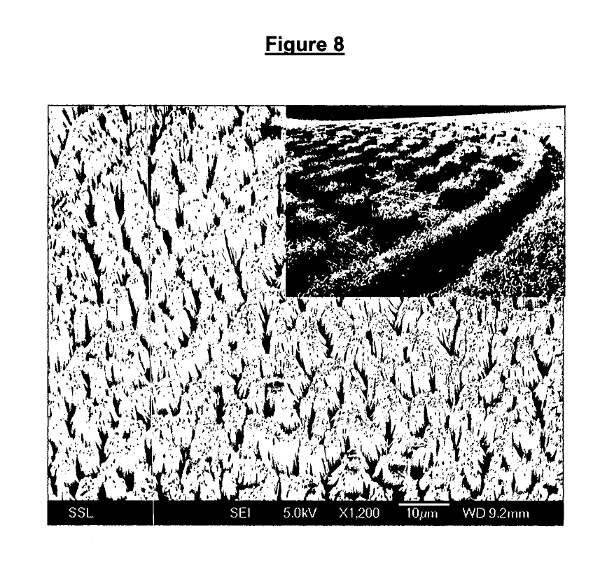

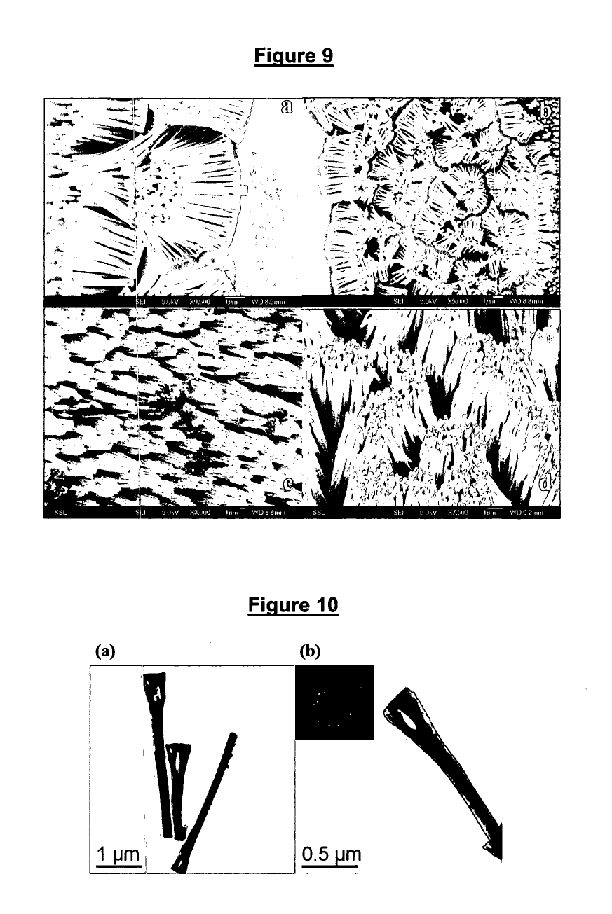

FIGS. 6(c) and 6(d) show some interesting islands comprised of nickel nanowires. As shown in the micrograph, some nanowires are up-standing in high order, but at the top, some of them are inclined to aggregate together. An SEM image showing the multiped heads of the nanowires is shown in FIG. 7. This phenomenon becomes more obvious as the length of the nanowires increases, as observed in FIG. 8 and FIG. 9. When the length of the nickel nanowire grows to about 7 μm, almost all the nanowires are assembled into bundles to form a ‘crop circle’ structure, as seen from the insert of FIG. 8. Similar phenomenon has been seen in some magnetic materials (Z. A. Hu and H. L. Li, 2005). When the AAO template was removed, the top side of the nanowires is more free-standing than the bottom side, so the top of the nickel nanowires may assemble together under the magnetic effect to form “islands”. It was observed that the formation of “islands” was only detected in magnetic material nanowire arrays.

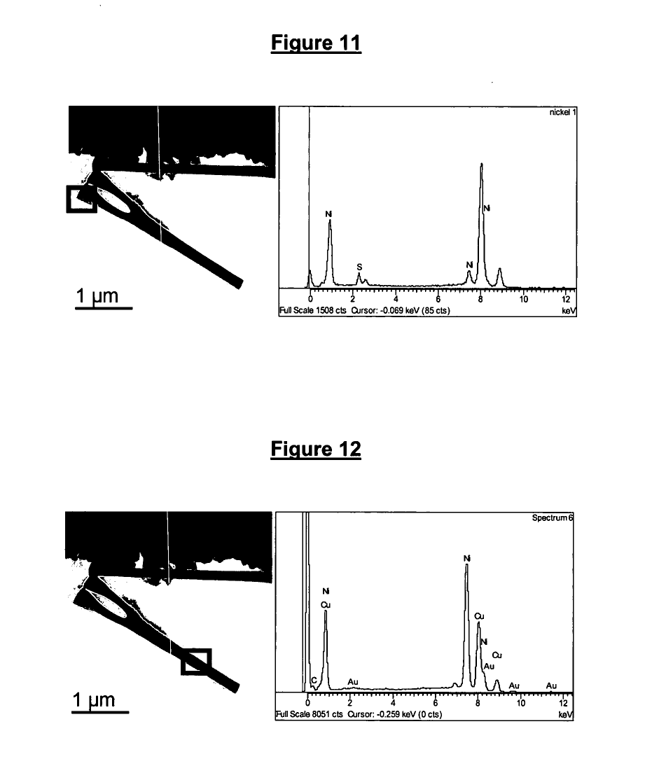

The TEM image of the separated nickel nanowire prepared from the method described above is shown in FIGS. 10(a) and (b). Evidence of growth from the split-pore region into larger pores shows how they replicate the template structure. FIG. 10(a) shows a multiped head on each nanowire. The insert of FIG. 10(b) is the corresponding electron diffraction pattern of the nickel nanowire, which indicates that the nanowire is polycrystalline. The existence of S in the root part of the nanowire is verified by Energy dispersive X-ray spectroscopy (EDX). The result is shown in FIG. 11 and FIG. 12, which exhibits the presence and absence of S in the root part and trunk of the nanowire respectively.

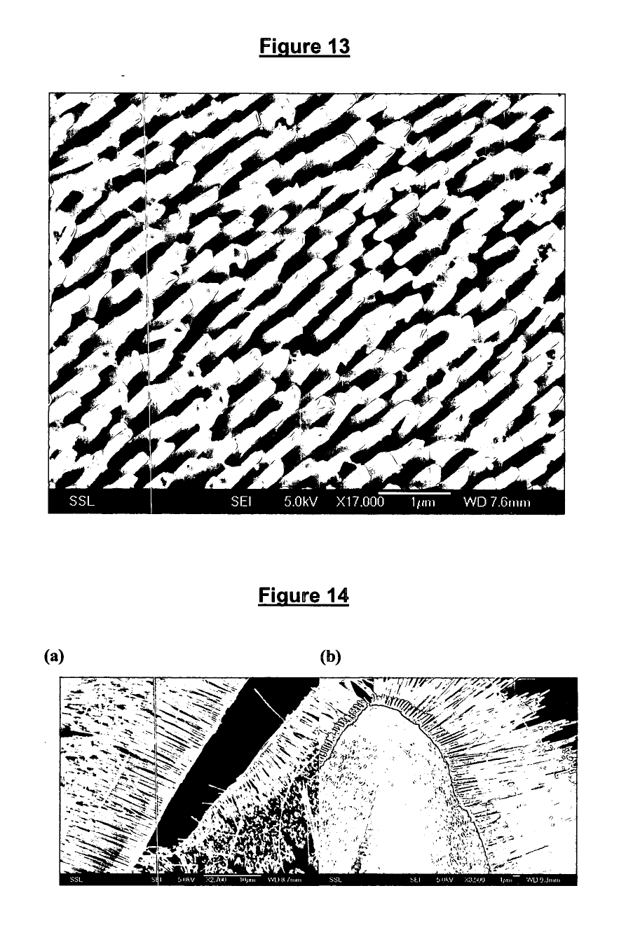

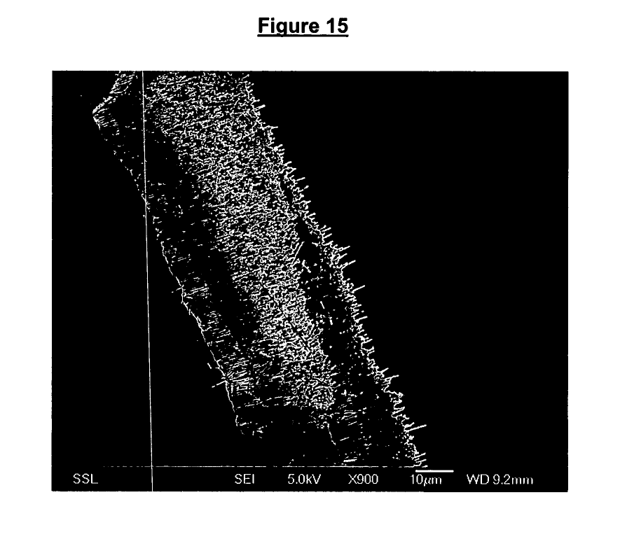

Based on the method described above, various kinds of free-standing and well-aligned nanowire arrays were formed in large scale and high quality. The various nanowires obtained are shown in FIGS. 13 to 15.

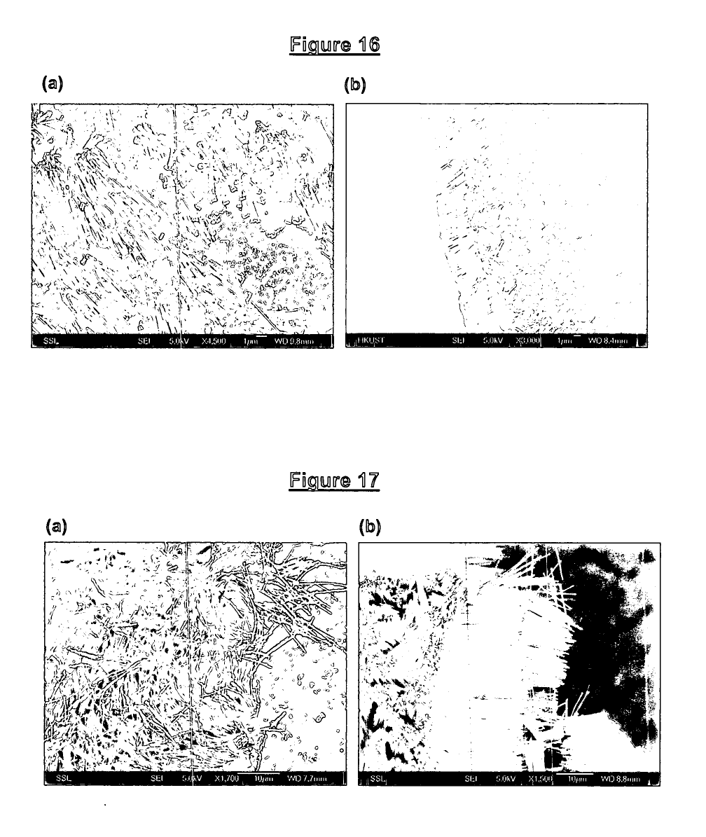

To observe how well-aligned and free-standing the nanowires prepared according to the method of the invention were, the prepared nanowires were subjected to sonication as described above. SEM images of the Ni and Cu nanowires after sonication are shown in FIG. 16 and FIG. 17 respectively. It can be seen that the Ni and Cu nanowires which were prepared without the use of an organic linker are randomly dispersed on the electrically conductive substrate (FIGS. 16(a) and 17(a)), while the Ni and Cu nanowires prepared using the method of the present invention remain well-ordered and well-aligned even after sonication, as seen in FIGS. 16(b) and 17(b).

It is observed that the use of organic linker groups that can self-assemble onto metal substrates (electrically conductive element) to direct and enhance the formation of nanowires via electrochemical deposition is advantageous. This has drastically improved the yield of nanowire formation by conventional electrochemical deposition method. The organic linkers may serve as a bridging group between the nanowires and the electrically conductive element, thus free-standing and well-aligned nanowire arrays can be formed in large scale and remain free-standing and well-aligned even after the removal of the template.

### REFERENCES

1. A. J. Yin, J. Li, W. Jian, A. J. Bennett, and J. M. Xu, Applied Physics Letters, 79:1039-1041, 2001

2. B. C. Bunker, P. C. Rieke, B. J. Tarasevich, A. A. Campbell, G. E. Fryxell, G. L. Graff, L. Song, J. Liu, J. W. Virden, G. L. Mevay, Science, 264:48-55, 1994

3. Chia-Chun Chen and Jan-Jan Lin, Adv. Mater., 13:136-139, 2001

4. D. Benerjee et al, Applied Physics Letters, 83:2061-2063, 2003

5. H. Masuda and K. Fukuda, Science, 268:1466-1468, 1995

6. J. Christopher Love, Lara A. Estroff, Jennah K. Kriebel et al, Chem. Rev., 105:1103-1169, 2005

7. J. L. Simonds, Phys. Today 48, 26, 1995

8. K. Hata, M. Fujita, S. Yoshida, S. Yasuda, T. Makimura, K. Murakami, H. Shigekawa, W. Mizutani and H. Tokumoto, Applied Physics Letters, 79(5):692-694, 2001

9. K. R. Pirota, D. Navas, M. Hernandez-Velez, K. Nielsch, M. Vazquez, Journal of Alloys and Compounds, 369:18-26, 2004

10. Leonard J. Prins, Jurriaan Huskens, Feike de Jong, Peter Timmerman & David N. Reinhoudt, Nature, 398:495-498, 1999

11. M. Motoyama, Y. Fukunaka, T. Sakka, Y. H. Ogata, S. Kikuchi, Journal of Electroanalytical Chemistry, 584: 84-91, 2005

12. S. Y. Chou, M. S. Wei, P. R. Krauss, and P. B. Fisher, Journal of Applied Physics, 76:6673, 1994

13. S. Manalis, K. abcock, J. Massie, V. Elings and M. Dugas, Applied Physics Letters, 66:2585, 1995

14. T. M. Whitney, J. S. Jiang, P. C. Searson, C. L. Chien, Science, 261:1316-1319, 1993

15. Y onggi Liang, Changgua Zhen, Dechun Zou and Dongsheng Xu, J. Am. Chem. Soc., 126(50):16338-16339, 2004

16. Z. A. Hu and H. L. Li, Journal of Materials Science: Materials in Electronics, 16:477-481, 2005

1. A method of preparing at least one nanowire comprising the steps of:
(a) providing at least one nanotemplate and at least one electrically conductive element in contact with the nanotemplate;
(b) providing at least one organic linker, the organic linker having a first end and a second end, such that the first end is in contact with the electrically conductive element; and
(c) performing at least one electrochemical deposition for the formation of at least one nanowire.

2. The method according to claim 1, wherein the first end of the organic linker comprises an anchoring group having an affinity for the at least one electrically conductive element and/or the second end of the organic linker comprises an end group having an affinity for the at least one nanowire.

3. The method according to claim 2, wherein the anchoring group comprises a group selected from: —SH, —CN, —COOH, —OH and —NH₂.

4. The method according to claim 1, wherein the at least one nanowire is formed on the electrically conductive element and/or on the second end of the at least one organic linker.

5. The method according to claim 4, wherein the at least one nanowire is formed on the second end of at least two organic linkers.

6. The method according to claim 1, wherein the at least one electrically conductive element is an electrically conductive layer.

7. The method according to claim 1, wherein the at least one electrically conductive element contacts the nanotemplate on one surface of the nanotemplate.

8. The method according to claim 1, wherein the nanotemplate is anodic aluminium oxide and/or titanium oxide.

9. The method according to claim 1, wherein the organic linker is selected from the group consisting of: ROH; RCOOH; RNH₂; RSH; RSAc; RSR′; and RSSR′, wherein each R and R′ is independently selected from the following: substituted or unsubstituted alkyl, alkenyl, alkynyl, aryl, cycloalkyl, cycloalkylene, cycloalkynyl, cycloaryl, heteroaryl, heteroalkyl, heterocycloaryl and heterocycloalkyl.

10. The method according to claim 9, wherein the organic linker is 11-mercaptoundecanoic acid (MUA).

11. The method according to claim 1, wherein the electrochemical deposition of step (c) is performed in the presence of an electrolyte.

12. The method according to claim 11, wherein the electrolyte is selected from the group consisting of: CuSO₄.6H₂O, NiSO₄.6H₂O, NiCl₂.6H₂O, H₃BO₃, AgNO₃, PbSO₄ and a combination thereof.

13. The method according to claim 1, wherein the at least one nanowire formed in step (c) is a first segment of at least one segmented nanowire.

14. The method according to claim 13, further comprising a step of: (d) performing at least one further electrochemical deposition for the formation of at least one! further segment wherein the at least one further segment is joined to the first segment.

15. The method according to claim 14, wherein the first segment and the further segment are longitudinally adjacent.

16. The method according to claim 14, wherein the at least one further segment is the same as or different from the first segment.

17. The method according to claim 1, further comprising the step of removing the at least one nanotemplate after the formation of the at least one nanowire.

18. The method according to claim 17, wherein the step of removing the at least one nanotemplate comprises dissolving the at least one nanotemplate in a solvent.

19. The method according to claim 18, wherein the solvent is aqueous NaOH and/or HF.

20. The method according to claim 1, wherein at least about 50% of the nanowires formed are parallel to one another.

21. Nanowires prepared according to the method of claim 1.

22. The nanowires according to claim 21, wherein the nanowires are comprised in a nanowire-based device.

23. The nanowires according to claim 22, wherein the nanowire-based device is selected from the group consisting of: magnetic recording devices, sensors, circuit elements, radiation detectors and thermophotolytic devices.

24. An array of nanowires comprising nanowires prepared according to the method of claim 1.

25. A nanowire, wherein the nanowire is in contact with one end of at least one organic linker.

26. The nanowire according to claim 25, wherein the nanowire is substantially vertical relative to a horizontal plane.
